(19) United States
(12) Patent Application Publication
(10) Pub. No.: US 2008/0041720 A1
(43) Pub. Date: Feb. 21, 2008

(54) Novel manufacturing design and processing methods and apparatus for PVD targets

(76) Inventors: Jaeyeon Kim, Liberty Lake, WA (US); Susan D. Strothers, Spokane, WA (US); Ira G. Nolander, Spokane, WA (US)

Correspondence Address: BUCHALTER NEMER, 18400 VON KARMAN AVE., SUITE 800, IRVINE, CA, 92612, US

(21) Appl. No.: 11/504,130

(22) Filed: Aug. 14, 2006

(51) Int. Cl. C23C 14/00

(52) U.S. Cl. 204/298.12

(57) ABSTRACT

Methods for producing PVD sputtering targets comprising extended sidewalls are described that include: a) bonding a surface material to a core material to produce a rough part; b) forming the rough part; and in some embodiments, c) utilizing at least one machining step to form the target. In addition, methods for producing PVD sputtering targets comprising extended sidewalls are described herein that include: a) concurrently bonding a surface material to a core material to produce a rough part and forming the rough part; and in some embodiments, b) utilizing at least one machining step to form the target. PVD sputtering targets and related apparatus formed by and utilizing these methods are also described herein.

### FIELD OF THE INVENTION

The field of the invention is manufacturing design and processing methods and apparatus for producing PVD targets having extended sidewalls.

### BACKGROUND

Electronic and semiconductor components are used in ever increasing numbers of consumer and commercial electronic products, communications products and data-exchange products. As the demand for consumer and commercial electronics increases, there is also a demand for those same products to become smaller and more portable for the consumers and businesses.

As a result of the size decrease in these products, the components that comprise the products must also become smaller and/or thinner. Examples of some of those components that need to be reduced in size or scaled down are microelectronic chip interconnections, semiconductor chip components, resistors, capacitors, printed circuit or wiring boards, wiring, keyboards, touch pads, and chip packaging.

When electronic and semiconductor components are reduced in size or scaled down, any defects that are present in the larger components are going to be exaggerated in the scaled down components. Thus, the defects that are present or could be present in the larger component should be identified and corrected, if possible, before the component is scaled down for the smaller electronic products.

In order to identify and correct defects in electronic, semiconductor and communications components, the components, the materials used and the manufacturing processes for making those components should be broken down and analyzed. Electronic, semiconductor and communication/data-exchange components are composed, in some cases, of layers of materials, such as metals, metal alloys, ceramics, inorganic materials, polymers, or organometallic materials. The layers of materials are often thin (on the order of less than a few tens of angstroms in thickness). In order to improve on the quality of the layers of materials, the process of forming the layer—such as physical vapor deposition of a metal or other compound—should be evaluated and, if possible, improved.

In a typical physical vapor deposition (PVD) process, a sample or target is bombarded with an energy source such as a plasma, laser or ion beam, until atoms are released into the surrounding atmosphere. The atoms that are released from the sputtering target travel towards the surface of a substrate (typically a silicon wafer) and coat the surface forming a thin film or layer of a material. Atoms are released from the sputtering target 10 and travel on an ion/atom path 30 towards the wafer or substrate 20, where they are deposited in a layer.

Prior Art FIGS. 1-12 show different target geometries, as various manufacturers have tried to address difficulties with target geometries Prior Art FIGS. 1 and 2 show an isometric view and cross-sectional side view, respectively, of an Applied Materials Self-Ionized Plasma Plus™ target construction 10. Prior Art FIGS. 3 and 4 show an isometric view and a cross-sectional side view, respectively, of a Novellus Hollow Cathode Magnetron™ target construction 12. Prior Art FIGS. 5 and 6 show an isometric and cross-sectional side view, respectfully, of an Applied Materials Endura™ target construction 14. Prior Art FIGS. 7 and 8 show an isometric and cross-sectional side view, respectively, of a flat target construction 16. Prior Art FIGS. 9 and 10 show a top view and a cross-sectional side view, respectively, of a Tokyo Electron Limited (TEL) target construction 18. Prior Art FIGS. 11 and 12 show a top view and cross-sectional side view, respectively, of an ULVAC target construction 20.

The Applied Materials™ target (Prior Art FIG. 2) and Novellus™ target (Prior Art FIG. 4) can be considered to comprise complex three-dimensional geometries, in that it is difficult to fabricate monolithic targets having the geometries of such targets. The Applied Materials™ target and Novellus™ target both share the geometrical characteristic of comprising at least one cup 11, having a pair of opposing ends 13 and 15. End 15 is open and end 13 is closed. The cups 11 have hollows 19 extending therein. In addition, each cup 11 has an internal (or interior) surface 21 defining a periphery of the hollow 19, and an exterior surface 23 in opposing relation to the interior surface. The exterior surface 23 extends around each cup 11, and wraps around the closed ends 13 at corners 25. Targets 10 and 12 each have a sidewall 27 defined by an exterior surface and extending between the ends 13 and 15. The targets of 10 and 12 of Prior Art FIGS. 2 and 4 further share the characteristic of a flange 29 extending around the sidewall 27. A difference between the target 12 of Prior Art FIG. 4 relative to the target 10 of Prior Art FIG. 2 is that target 10 has a cavity 17 extending downwardly through a center of the target to narrow the cup 11 of target 10 relative to the cup of target 12.

Each of the cross-section side views of the Prior Art Figures disclosed above is shown comprising horizontal dimensions “x” and vertical dimensions “y”. The ratio of “y” to “x” can determine if the target is a so-called three-dimensional target or a two-dimensional target. Specifically, each of the targets described above comprises a horizontal dimension “x” from about 15 inches to about 21 inches. The vertical dimension “y” of these same targets ranges from about 1 inch to about 10 inches.

Conventional PVD targets with extended side wall configurations are typically manufactured by utilizing electron-beam welding or “E-beam” welding to attach the sputtering material to the backing/plate or substrate material. A contemplated E-beam process flow chart is shown in Prior Art FIG. 13. In this flow chart 100, square steps represent process steps, oval steps represent inspection steps and combination square/wavy steps represent where records were kept. Specifically, the material for the target is cast 105 and preparation for a high purity target blank begins 110. The TMP 115, saw blanks 120 and grain size measure 125 steps follow. At this point, a quality analysis step 130 can be performed on the blank. The blank is then machined 135, E-beam welded 140 and checked for leaks 145. The blank then goes through final machining 150 and pre-cleaning 155. The dimensions are inspected 160 and the target auto-cleaned 165 and shipped 170.

One of the primary problems with the E-beam process is that it can generate weld pits and small cracks in the materials, which are potential arc sources that generate particles during sputtering. The particles can lead to significant and detrimental yield problems for the devise manufacturer. In addition, welds can give rise to mechanical strength gradients across at the joined interface in configurations with thin sidewalls.

Larger sputtering targets are being manufactured in order to address larger wafers, larger applications and also in an effort to improve the consistency of the layer produced on the substrate. As the size of sputtering target increases, the demands on the mechanical integrity of the assembly increases. This presents challenges in the manufacturing of the assemblies and in the choice of materials used for the backing plate member.

To this end, it would be desirable to produce a PVD target and target/wafer assembly that a) can be manufactured efficiently with the minimum number of processing steps to produce the final product; b) can eliminate potential arc sources in the assembly, c) and is produced by a method that provides the flexibility of manipulating the bond line location to maximize the overall strength of the assembly in configurations with thin side-walls.

### SUMMARY OF THE INVENTION

Methods for producing PVD sputtering targets comprising extended sidewalls are described that include: a) solid state bonding a surface material to a core material to produce a rough part; b) forming the rough part, wherein the part comprises extended sidewalls. In some embodiments, the methods will further comprise utilizing at least one machining step to form the target.

In addition, methods for producing PVD sputtering targets are described herein that include: a) concurrently solid state bonding a surface material to a core material to produce a rough part and forming the rough part, wherein the part comprises extended sidewalls. In some embodiments, the methods will further comprise utilizing at least one machining step to form the target.

PVD sputtering targets and related apparatus formed by and utilizing these methods are also described herein. In addition, uses of these PVD sputtering targets are described herein.

### BRIEF DESCRIPTION OF THE FIGURES

Prior Art FIGS. 1 and 2 show an isometric view and cross-sectional side view, respectively, of an Applied Materials Self-ionized Plasma Plus™ target construction 10.

Prior Art FIGS. 3 and 4 show an isometric view and a cross-sectional side view, respectively, of a Novellus Hollow Cathode Magnetron™ target construction 12.

Prior Art FIGS. 5 and 6 show an isometric and cross-sectional side view, respectfully, of an Applied Materials Endura™ target construction 14.

Prior Art FIGS. 7 and 8 show an isometric and cross-sectional side view, respectively, of a flat target construction 16.

Prior Art FIGS. 9 and 10 show a top view and a cross-sectional side view, respectively, of a Tokyo Electron Limited (TEL) target construction 18.

Prior Art FIGS. 11 and 12 show a top view and cross-sectional side view, respectively, of an ULVAC target construction 20.

Prior Art FIG. 13 shows a conventional E-beam process flow diagram.

FIG. 14 shows a contemplated process utilizing uni-axial contact die forging.

FIG. 15 shows a contemplated process utilizing press-forming (hydro-forming).

FIG. 16 shows a contemplated process utilizing a combination of diffusion bonding and press-forming.

FIG. 17 shows a contemplated diffusion bonding process flow diagram.

### DESCRIPTION OF THE SUBJECT MATTER

A PVD target assembly has been produced that a) eliminates pits and cracks at the interface of the sputtering material and supporting member, b) provides for flexibility in the location of the bond line to maximize the mechanical integrity of the assembly, and c) is manufactured efficiently with the minimum number of processing steps to produce the final product. For the purposes of interpreting this disclosure and the claims that follow, a target is considered to have an extended sidewall if the ratio of the vertical dimension “y” to the horizontal dimension “x” is at least about 0.125. In some embodiments, the ratio of the vertical dimension to the horizontal division is at least about 0.200. In other embodiments, the ratio of the vertical dimension to the horizontal division is at least about 0.225. In yet other embodiments, the ratio of the vertical dimension to the horizontal division is at least about 0.275.

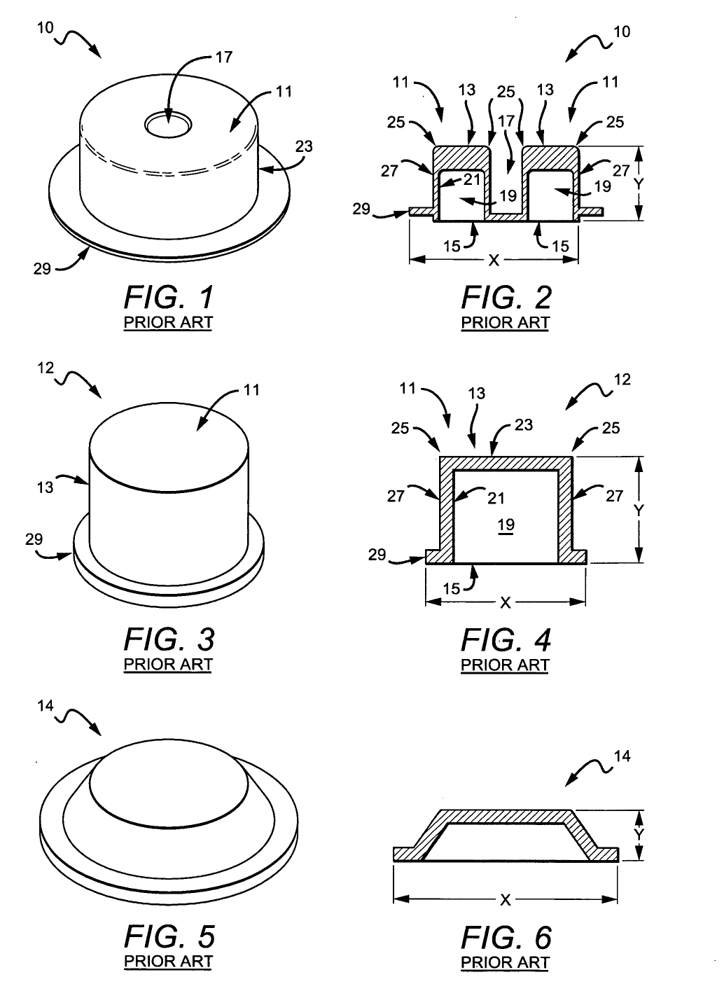

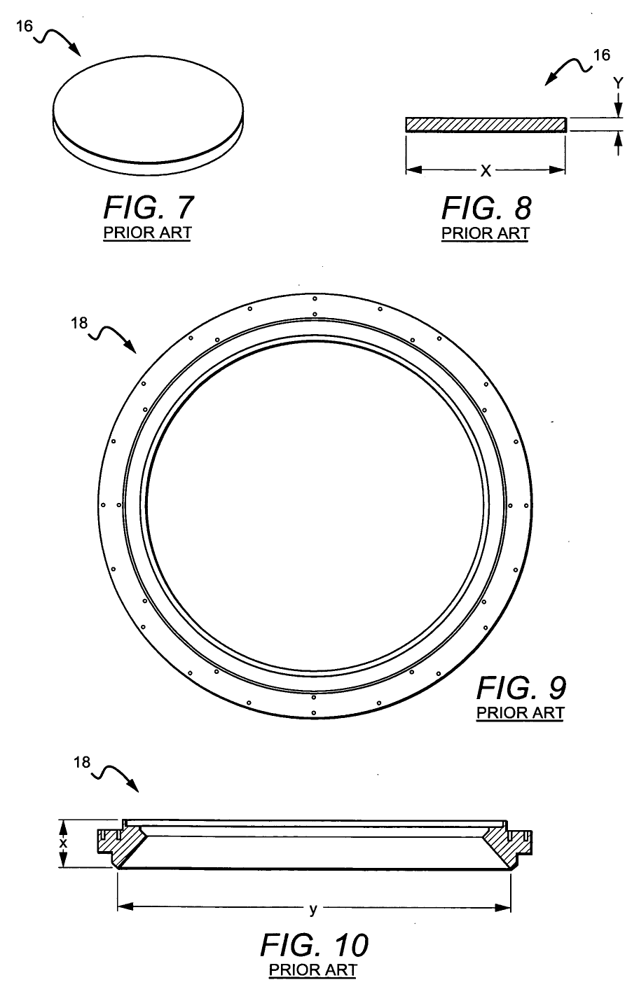

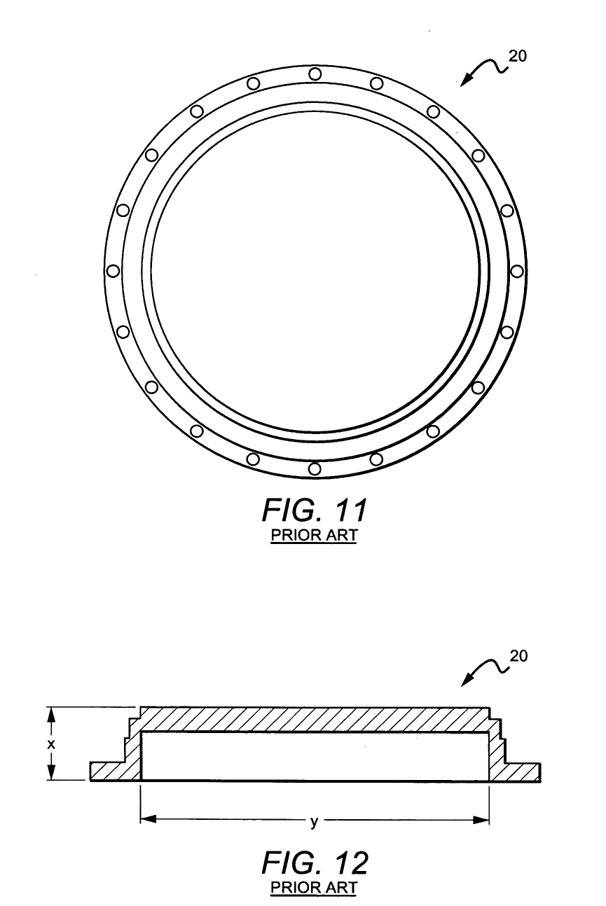

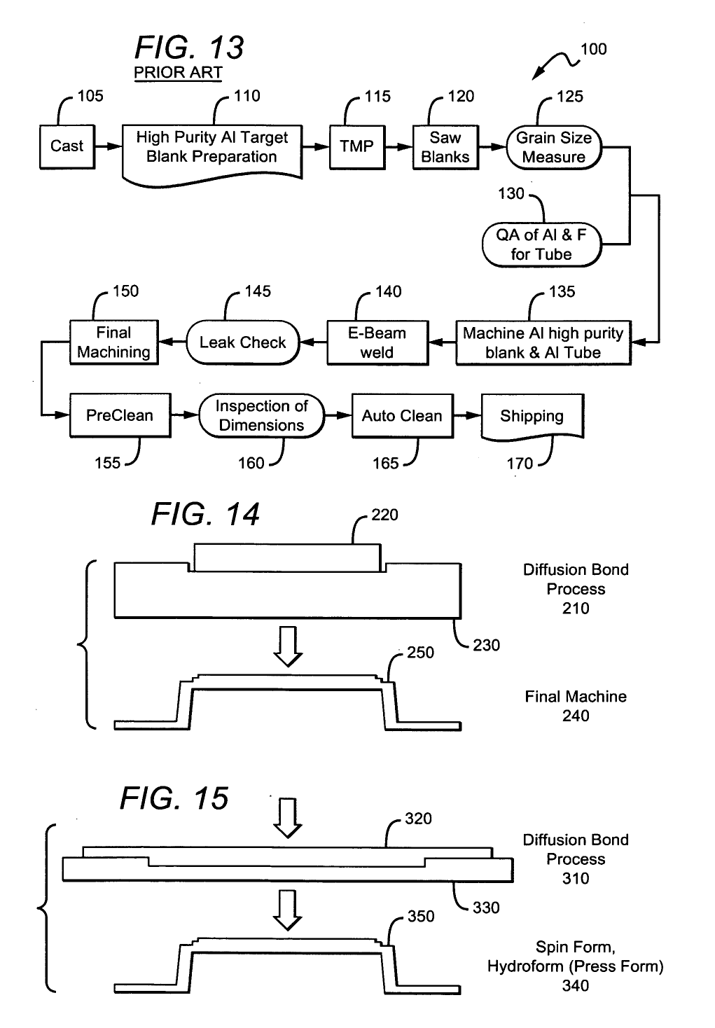

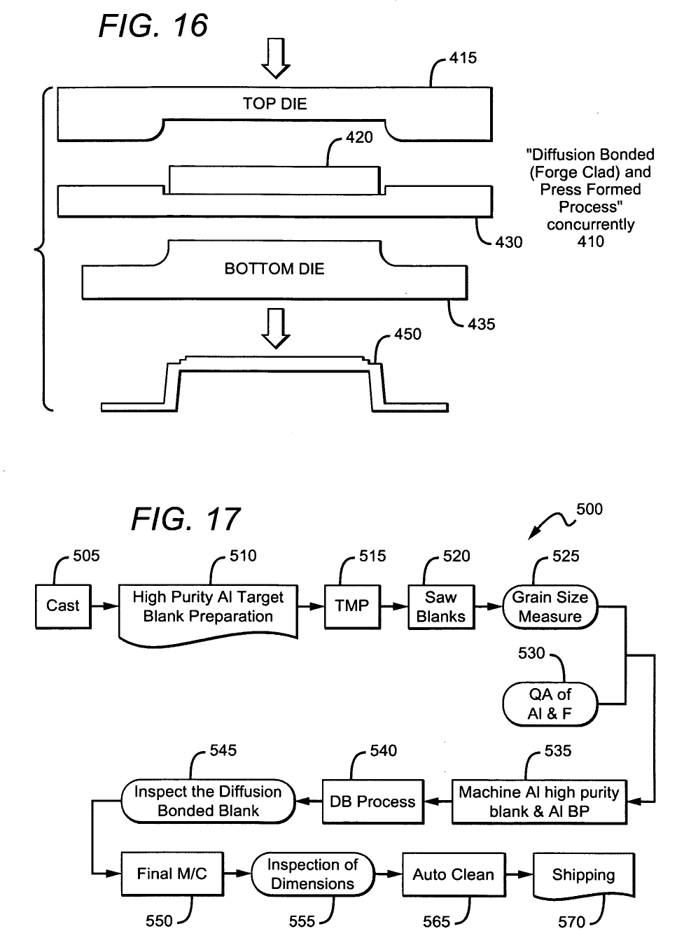

In accomplishing the manufacturing advances described herein, the E-beam welding processes have been replaced by at least one of the following solid state bonding and forming processes: a) uni-axial contact die forging (FIG. 14) showing the diffusion bond process 210 between a core material 220 and a surface material 230 and then producing a target 250 after a final machining step 240, b) hot isostatic processing (HIP), c) press forming or hydro-forming 340 after the diffusion bond process 310 between a core material 320 and a surface material 330 to form the final target 350 (FIG. 15), or d) concurrently bonding+spin forming/press forming 410 (FIG. 16) by utilizing a top die 415 and a bottom die 435 to press form the core material 420 and the surface material 430, which will form the final target 450. These processes are utilized either alone or in combination, followed by machining steps. Each of these processes—alone or in combination with one another (as shown in FIG. 17)—provide significant improvements over E-beam welding, especially when producing larger targets, such as the 300 mm ULVAC Entron EX PVD target—which is larger than typical planar 300 mm PVD targets. FIG. 17 shows a contemplated processing flow chart where diffusion bonding is utilized in place of E-beam welding. In this flow chart 500, square steps represent process steps, oval steps represent inspection steps and combination square/wavy steps represent where records were kept. Specifically, the material for the target is cast 505 and preparation for a high purity target blank begins 510. The TMP 515, saw blanks 520 and grain size measure 525 steps follow. At this point, a quality analysis step 530 can be performed on the blank. The blank is then machined 535, diffusion bonded 540 and inspected 545. The blank then goes through final machining 550 and inspection of dimensions 555. The target is then auto-cleaned 565 and shipped 570.

Methods for producing PVD sputtering targets include: a) bonding a surface material to a core material to produce a rough part; b) forming the rough part; and optionally in some embodiments, c) utilizing at least one machining step to form the target. In addition, methods for producing PVD sputtering targets include: a) concurrently bonding a surface material to a core material to produce a rough part and forming the rough part; and optionally, in some embodiments, b) utilizing at least one machining step to form the target

In one contemplated method to produce these PVD targets, a solid state/diffusion bonded rough part is manufactured, the part is then formed utilizing a forming method, such as spin-forming or press forming, and then at least one machining step is conducted on the spin formed or press formed part (for example, the rough blank). In some embodiments, these methods and processes can be combined or conducted concurrently to produce a more efficient and economical method. For example, as shown in FIG. 16, diffusion bonding (forge clad) and press forming are combined and conducted concurrently.

Diffusion bonding the part comprises bonding the sputtering material to the backing plate by any suitable solid state bonding method—such as uni-axial contact die forging, explosion bonding, friction bonding, or hot isostatic pressing (HIP). The rough blank is then spin-formed or press formed instead of rough machining to shape and form the backside (backing plate) of the target. Finally, at least one machining step is performed on the rough target to produce the final target. The resulting target comprises fewer defects (such as weld pits) than those made by conventional E-beam welding and also is made using fewer processing steps.

The methods and apparatus described herein are especially useful in producing unconventional, uniquely-sized targets, such as the 300 mm ULVAC Entron EX PVD target and new targets being produced to utilize in the production of large LCD and plasma displays.

Sputtering targets and sputtering target assemblies contemplated and produced herein comprise any suitable shape and size depending on the application and instrumentation used in the PVD process. Sputtering targets contemplated and produced herein comprise a surface material and a core material (which includes the backing plate). The surface material and core material may generally comprise the same elemental makeup or chemical composition/component, or the elemental makeup and chemical composition of the surface material may be altered or modified to be different than that of the core material. However, in embodiments where it may be important to detect when the target's useful life has ended or where it is important to deposit a mixed layer of materials, the surface material and the core material may be tailored to comprise a different elemental makeup or chemical composition.

The surface material is that portion of the target that is intended to produce atoms and/or molecules that are deposited via PVD to form the surface coating/thin film.

Sputtering targets contemplated herein may generally comprise any material that can be a) reliably formed into a sputtering target; b) sputtered from the target when bombarded by an energy source; and c) suitable for forming a final or precursor layer on a wafer or surface. Materials that are contemplated to make suitable sputtering targets are metals, metal alloys, conductive polymers, conductive composite materials, dielectric materials, hardmask materials and any other suitable sputtering material. As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, iron, zinc, vanadium, zirconium, aluminum and aluminum-based materials, tantalum, niobium, tin, chromium, platinum, palladium, gold, silver, tungsten, molybdenum, cerium, promethium, thorium, ruthenium or a combination thereof. More preferred metals include copper, aluminum, tungsten, titanium, cobalt, tantalum, magnesium, lithium, silicon, manganese, iron or a combination thereof. Most preferred metals include copper, aluminum and aluminum-based materials, tungsten, titanium, zirconium, cobalt, tantalum, niobium, ruthenium or a combination thereof. Examples of contemplated and preferred materials, include aluminum and copper for superfine grained aluminum and copper sputtering targets; aluminum, copper, cobalt, tantalum, zirconium, and titanium for use in 200 mm and 300 mm sputtering targets, along with other mm-sized targets; and aluminum for use in aluminum sputtering targets that deposit a thin, high conformal “seed” layer or “blanket” layer of aluminum surface layers. It should be understood that the phrase “and combinations thereof” is herein used to mean that there may be metal impurities in some of the sputtering targets, such as a copper sputtering target with chromium and aluminum impurities, or there may be an intentional combination of metals and other materials that make up the sputtering target, such as those targets comprising alloys, borides, carbides, fluorides, nitrides, silicides, oxides and others.

The term “metal” also includes alloys, metal/metal composites, metal ceramic composites, metal polymer composites, as well as other metal composites. Alloys contemplated herein comprise gold, antimony, arsenic, boron, copper, germanium, nickel, indium, palladium, phosphorus, silicon, cobalt, vanadium, iron, hafnium, titanium, iridium, zirconium, tungsten, silver, platinum, ruthenium, tantalum, tin, zinc, lithium, manganese, rhenium, and/or rhodium. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, palladium nickel, platinum palladium, palladium rhenium, platinum rhodium, silver arsenic, silver copper, silver gallium, silver gold, silver palladium, silver titanium, titanium zirconium, aluminum copper, aluminum silicon, aluminum silicon copper, aluminum titanium, chromium copper, chromium manganese palladium, chromium manganese platinum, chromium molybdenum, chromium ruthenium, cobalt platinum, cobalt zirconium niobium, cobalt zirconium rhodium, cobalt zirconium tantalum, copper nickel, iron aluminum, iron rhodium, iron tantalum, chromium silicon oxide, chromium vanadium, cobalt chromium, cobalt chromium nickel, cobalt chromium platinum, cobalt chromium tantalum, cobalt chromium tantalum platinum, cobalt iron, cobalt iron boron, cobalt iron chromium, cobalt iron zirconium, cobalt nickel, cobalt nickel chromium, cobalt nickel iron, cobalt nickel hafnium, cobalt niobium hafnium, cobalt niobium iron, cobalt niobium titanium, iron tantalum chromium, manganese iridium, manganese palladium platinum, manganese platinum, manganese rhodium, manganese ruthenium, nickel chromium, nickel chromium silicon, nickel cobalt iron, nickel iron, nickel iron chromium, nickel iron rhodium, nickel iron zirconium, nickel manganese, nickel vanadium, tungsten titanium and/or combinations thereof.

As far as other materials that are contemplated herein for sputtering targets, the following combinations are considered examples of contemplated sputtering targets (although the list is not exhaustive): chromium boride, lanthanum boride, molybdenum boride, niobium boride, tantalum boride, titanium boride, tungsten boride, vanadium boride, zirconium boride, boron carbide, chromium carbide, molybdenum carbide, niobium carbide, silicon carbide, tantalum carbide, titanium carbide, tungsten carbide, vanadium carbide, zirconium carbide, aluminum fluoride, barium fluoride, calcium fluoride, cerium fluoride, cryolite, lithium fluoride, magnesium fluoride, potassium fluoride, rare earth fluorides, sodium fluoride, aluminum nitride, boron nitride, niobium nitride, silicon nitride, tantalum nitride, titanium nitride, vanadium nitride, zirconium nitride, chromium silicide, molybdenum silicide, niobium silicide, tantalum silicide, titanium silicide, tungsten silicide, vanadium silicide, zirconium silicide, aluminum oxide, antimony oxide, barium oxide, barium titanate, bismuth oxide, bismuth titanate, barium strontium titanate, chromium oxide, copper oxide, hafnium oxide, magnesium oxide, molybdenum oxide, niobium pentoxide, rare earth oxides, silicon dioxide, silicon monoxide, strontium oxide, strontium titanate, tantalum pentoxide, tin oxide, indium oxide, indium tin oxide, lanthanum aluminate, lanthanum oxide, lead titanate, lead zirconate, lead zirconate-titanate, titanium aluminide, lithium niobate, titanium oxide, tungsten oxide, yttrium oxide, zinc oxide, zirconium oxide, bismuth telluride, cadmium selenide, cadmium telluride, lead selenide, lead sulfide, lead telluride, molybdenum selenide, molybdenum sulfide, zinc selenide, zinc sulfide, zinc telluride and/or combinations thereof.

Thus, specific embodiments and applications of methods of manufacturing PVD targets and related apparatus have been disclosed. It should be apparent, however, to those skilled in the art that many more modifications besides those already described are possible without departing from the inventive concepts herein. The inventive subject matter, therefore, is not to be restricted except in the spirit of the disclosure and claims herein. Moreover, in interpreting the disclosure and claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A method for producing a PVD sputtering target with an extended sidewall, comprising:
solid state bonding a surface material to a core material to produce a rough part;
forming the rough part, wherein the part comprises extended sidewalls.

2. The method of claim 1, wherein the part comprises a vertical dimension “y” and a horizontal dimension “x”.

3. The method of claim 2, wherein the ratio of y to x is at least about 0.125.

4. The method of claim 3, wherein the ratio of y to x is at least about 0.200.

5. The method of claim 1, wherein the bonding comprises at least one solid state bonding process.

6. The method of claim 5, wherein the at least one solid state/diffusion bonding process comprises uni-axial contact die forging, hot isostatic pressing, cold isostatic pressing, friction bonding, explosion bonding or a combination thereof.

7. The method of claim 1, wherein the core material comprises a backing plate/support member.

8. The method of claim 1, wherein the surface material comprises a sputtering material.

9. The method of claim 1, wherein the surface material and the core material comprises the same materials.

10. The method of claim 1, wherein forming the rough part comprises utilizing a press-forming process, a hydro-forming process, a spin-forming process, a deep drawing process, or a combination thereof.

11. The method of claim 1, wherein the bonding step and the forming step are performed concurrently.

12. The method of claim 1, wherein the bonding step and the forming step are performed in a step-wise manner.

13. A method for producing a PVD sputtering target, comprising:
concurrently bonding a surface material to a core material to produce a rough part and forming the rough part; and
utilizing at least one machining step to form the target.

14. A PVD sputtering target produced by the method of claim 1.

15. A PVD sputtering target produced by the method of claim 13.

16. The PVD sputtering target of claim 13, further comprising an interlayer material at the interface of the solid state bond.

17. A PVD sputtering target assembly with an extended sidewall that consists essentially of solid state bonding to join the sputtering material to the support member.

18. A PVD sputtering target comprising a core material and a surface material, wherein the surface material is solid-state bonded to the core material.

19. The PVD sputtering target of claim 18, wherein the target comprises a vertical dimension “y” and a horizontal dimension “x”.

20. The PVD sputtering target of claim 19, wherein the ratio of y to x is at least about 0.125.
